(19) United States
(12) Patent Application Publication
(10) Pub. No.: US 2010/0098875 A1
(43) Pub. Date: Apr. 22, 2010

(54) PRE-COATING AND WAFER-LESS AUTO-CLEANING SYSTEM AND METHOD

(76) Inventors: Andreas Fischer, Castro Valley, CA (US); Maryam Moravej, Mountain View, CA (US)

Correspondence Address: TR Patents, L.L.C., 10351 Southern MD BLVD Suite 102, P.O Box 361, Dunkirk, MD, 20754, US

(21) Appl. No.: 12/253,511

(22) Filed: Oct. 17, 2008

(51) Int. Cl. C23C 14/58; H05H 1/24

(52) U.S. Cl. 427/534; 427/569

(57) ABSTRACT

In a wafer processing system having an electrode, an electrostatic chuck (ESC) and a confinement chamber portion, the ESC is established to be RF-floating, whereas a confinement chamber portion is grounded during a pre-coating process. Accordingly, the confinement chamber portion and the upper electrode are selectively targeted for pre-coating material deposition. As such, the amount of pre-coating material that is deposited onto the ESC is greatly reduced over that of conventional systems. Therefore, less time, energy and material are needed to remove pre-coating material from the ESC during a wafer auto clean (WAC) process. Further, the upper electrode is established to be RF-floating, whereas the confinement chamber portion is grounded during a WAC process. As such, the cleaning material is selectively targeted toward the confinement hardware portion of the chamber. Therefore, the upper electrode is subjected to less wear during a WAC process.

### BACKGROUND

The semiconductor manufacturing industry places an increased emphasis on cost savings to increase a constantly dwindling profit margin. One important effort to drive costs lower is directed toward reducing the wear rate of plasma-exposed parts inside the reactor by applying a pre-coat deposition that is applied prior to the actual etching process. This pre-coat protects the underlying surface from direct plasma attack and is consumed during the etching process. Pre-coat remains are etched away after the wafer leaves the processing chamber in a wafer-less auto-clean (WAC) process. To minimize impact in throughput and ultimately cost of ownership, care must be taken that pre-coat and extra WAC time are kept at a minimum length.

FIG. 1 illustrates a conventional wafer processing system during a conventional pre-coating process. System 100 includes a confinement chamber portion 102, an electrode 104, an electro-static chuck (ESC) 106, an upper radio frequency (RF) driver 108 connected to electrode 104, a lower RF driver 110 connected to ESC 106 and an exhaust portion 114. A plasma-forming space 112 is bounded by electrode 104, ESC 106, and confinement chamber portion 102.

In order to reduce damage to confinement chamber portion 102 and electrode 104 during the wafer processing process, a pre-coating material is typically deposited on the surfaces of confinement chamber portion 102, electrode 104 and ESC 106 that are exposed to plasma-forming space 112. This is accomplished by providing a voltage differential either between electrode 104 and ground or ESC 106 and ground or both, via upper RF driver 108 and lower RF driver 110, while pressure is decreased in plasma-forming space 112. Further, a pre-coating material is supplied into plasma-forming space 112 via a pre-coating material source (not shown). The pressure within plasma-forming space 112 and the voltage differential, as created by at least one of upper RF driver 108 and lower RF driver 110, are set such that the pre-coating material supplied into plasma-forming space 112 creates plasma 116. Plasma 116 deposits the pre-coating material onto the surfaces of confinement chamber portion 102, electrode 104 and ESC 106 that are exposed to plasma-forming space 112.

FIG. 2 illustrates the conventional wafer processing system of FIG. 1, after a conventional pre-coating process. In the figure, plasma 116 has deposited a layer 208 of pre-coating material on a bottom surface 202 of electrode 104, an inner surface 204 of confinement chamber portion 102 and a top surface 206 of ESC 106.

As mentioned above, during the conventional pre-coating process, the portion of ESC 106 that is exposed to plasma-forming space 112 additionally has a layer of pre-coating material deposited thereon. The layer of pre-coating deposited on ESC 106 is not needed, as will be described in more detail below. Therefore, depositing the layer of the pre-coating on ESC 106 is a waste of time, energy and material. Further, removing the layer of pre-coating deposited on ESC 106 requires additional time, energy and money, which will additionally be described in more detail below.

FIG. 3 illustrates the conventional wafer processing system of FIG. 1, during a conventional wafer processing process. In the figure, a wafer 300 is held on ESC 106 via an electrostatic force. Again, a voltage differential is provided between electrode 104 and ESC 106, via upper RF driver 108 and lower RF driver 110, while pressure is decreased in plasma-forming space 112. Further, an etching material is supplied into plasma-forming space 112 via an etching material source (not shown). The pressure within plasma-forming space 112 and the voltage differential, as created by at least one of upper RF driver 108 and lower RF driver 110, are set such that the etching material supplied into plasma-forming space 112 creates plasma 302. Plasma 302 etches material within plasma-forming space 112, which includes wafer 300 in addition to layer 208 of pre-coating material on bottom surface 202 of electrode 104 and inner surface 204 of confinement chamber portion 102. Layer 208 of pre-coating material on bottom surface 202 of electrode 104 and inner surface 204 of confinement chamber portion 102 protects the underlying surfaces from direct plasma attack and is consumed during wafer processing.

FIG. 4 illustrates the conventional wafer processing system of FIG. 1, after a conventional wafer processing process. In the figure, wafer 300 has been removed from the top of ESC 106. The portion of layer 208 of pre-coating material on bottom surface 202 of electrode 104 has been removed because the amount of coating is typically pre-determined to last until in the end the wafer etching process to eliminate coating from electrode 104. However, a small layer 404 of pre-coating material remains on inner surface 204 of confinement chamber portion 102. More importantly, a relatively large layer 402 of pre-coating material remains on upper surface 206 of ESC 106. This is because upper surface 206 of ESC 106 is covered by wafer 300 during the etching process. Therefore, the portion of layer 208 of pre-coating material on upper surface 206 of ESC 106 is not subjected to plasma 302. As such, the portion of layer 208 of pre-coating material on upper surface 206 of ESC 106 is not etched away during the etching process.

In order to prepare for a new wafer processing session, layer 404 of pre-coating material on inner surface 204 of confinement chamber portion 102 and the portion of layer 208 of pre-coating material on upper surface 206 of ESC 106 must be removed. This is conventionally accomplished via a conventional wafer-less auto-clean (WAC) process.

FIG. 5 illustrates the conventional wafer processing system of FIG. 1, during a conventional WAC process. Again, a voltage differential is provided between electrode 104 and ESC 106, via upper RF driver 108 and lower RF driver 110, while pressure is decreased in plasma-forming space 112. Further, cleaning material is supplied into plasma-forming space 112 via a cleaning material source (not shown). The pressure within plasma-forming space 112 and the voltage differential, as created by at least one of upper RF driver 108 and lower RF driver 110, are set such that the cleaning material supplied into plasma-forming space 112 creates plasma 502. Plasma 502 etches material within plasma-forming space 112, which includes layer 404 of pre-coating material on inner surface 204 of confinement chamber portion 102 and layer 402 of pre-coating material on upper surface 206 of ESC 106.

The conventional WAC process, as illustrated in FIG. 5, continues until all the pre-coating material is removed. Because layer 402 of pre-coating material on upper surface 206 of ESC 106 is the thickest layer of pre-coating material, the conventional WAC process should continue until layer 402 is removed. As such, there is a period of time, after pre-coating material on inner surface 204 of confinement chamber portion 102 has been removed, that the conventional WAC process continues. During this period, inner surface 204 of confinement chamber portion 102 is needlessly subjected to plasma 502, which may negatively affect the lifespan of confinement chamber portion 102. Further, for the entire period of the conventional WAC process, bottom surface 202 of electrode 104 is needlessly subjected to plasma 502, which may negatively affect the lifespan of electrode 104.

After the above discussed process is completed, system 100 is ready for a new wafer processing session, starting again with the pre-coating process as illustrated in FIG. 1.

As mentioned above, one of the problems associated with the conventional wafer processing system is that time, energy, and material is wasted on unnecessarily coating ESC 106 and then cleaning ESC 106.

What it needed is a way to selectively deposit and remove pre-coating materials from within the plasma-forming space bounded by electrode, ESC, and the confinement chamber portion.

### BRIEF SUMMARY

It is an object of the present invention to provide a system and method selectively depositing and removing pre-coating materials from within the plasma-forming space bounded by an electrode, an ESC, and a confinement chamber portion of a deposition chamber.

An aspect of the present invention is drawn to a method of operating a wafer processing system having a electrode, an electrostatic chuck, a confinement chamber portion, a first radio frequency driving source, a second radio frequency driving source, a pre-coating material source, a cleaning material source, an exhaust portion and a switch system. The electrode is spaced from and opposes the electrostatic chuck. A plasma-forming space is bounded by the electrode, the electrostatic chuck and the confinement chamber portion. The first radio frequency driving source is arranged to be in electrical connection with the electrode via the switch system. The second radio frequency driving source is arranged to be in electrical connection with the electrostatic chuck via the switch system. The pre-coating material source is operable to provide a pre-coating material into the plasma-forming space. The cleaning material source is operable to provide a cleaning material into the plasma-forming space. The exhaust portion is operable to remove pre-coating material and cleaning material from the plasma-forming space. The method may include performing at least one of a pre-coating process and a cleaning process. The pre-coating process may include connecting the first radio frequency driving source to the electrode via the switch system, connecting the confinement chamber portion to ground, disconnecting the second radio frequency driving source from the electrostatic chuck via the switch system, disconnecting the electrostatic chuck from ground, supplying the pre-coating material into the plasma-forming space via the pre-coating material source, generating plasma within the plasma-forming space and coating the pre-coating material onto the confinement chamber portion. The cleaning process may include disconnecting the first radio frequency driving source from the electrode via the switch system, disconnecting the electrode from ground, connecting the confinement chamber portion to ground, connecting the second radio frequency driving source to the electrostatic chuck via the switch system, supplying the cleaning material into the plasma-forming space via the cleaning material source, generating plasma within the plasma-forming space and cleaning the pre-coating material from the confinement chamber portion.

Additional objects, advantages and novel features of the invention are set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate an exemplary embodiment of the present invention and, together with the description, serve to explain the principles of the invention. In the drawings:

FIG. 1 illustrates a conventional wafer processing system during a conventional pre-coating process;

FIG. 2 illustrates the conventional wafer processing system of FIG. 1, after a conventional pre-coating process;

FIG. 3 illustrates the conventional wafer processing system of FIG. 1, during a conventional wafer processing process;

FIG. 4 illustrates the conventional wafer processing system of FIG. 1, after a conventional wafer processing process;

FIG. 5 illustrates the conventional wafer processing system of FIG. 1, during a conventional WAC process;

FIG. 6 illustrates an exemplary wafer processing system during an exemplary pre-coating process in accordance with the present invention;

FIG. 7 illustrates the chamber system of FIG. 6, after an exemplary pre-coat process in accordance with the present invention;

FIG. 8 illustrates the chamber system of FIG. 6, during an exemplary wafer processing process in accordance with the present invention;

FIG. 9 illustrates the chamber system of FIG. 6, after an exemplary wafer processing process in accordance with the present invention;

FIG. 10 illustrates the chamber system of FIG. 6, during an exemplary WAC process in accordance with the present invention;

FIG. 11 illustrates another exemplary wafer processing system during an exemplary pre-coating process in accordance with the present invention;

FIG. 12 illustrates the chamber system of FIG. 11, during an exemplary WAC process in accordance with the present invention;

FIG. 13 is a chart comparing a conventional pre-coating process with a pre-coating process in accordance with the present invention; and

FIG. 14 is a chart comparing a conventional WAC process with a WAC process in accordance with the present invention.

### DETAILED DESCRIPTION

FIG. 6 illustrates an exemplary wafer processing system during an exemplary pre-coating process in accordance with the present invention. In the figure, system 600 includes a confinement chamber portion 602, an electrode 604, an ESC 606, an upper RF driver 608 connected to electrode 604, a lower RF driver 610 connectable to ESC 606 via a switch 620, and an exhaust portion 614. A plasma-forming space 612 is bounded by electrode 604, ESC 606, and confinement chamber portion 602. Further, confinement chamber portion 602 is grounded with ground connection 618.

In order to reduce damage to confinement chamber portion 602 and electrode 604 during the wafer processing process, a pre-coat is deposited on the surfaces of confinement chamber portion 602 and electrode 604 that are exposed to plasma-forming space 612. This is accomplished by providing a voltage differential between electrode 604 and confinement chamber portion 602, via upper RF driver 608, while the pressure is decreased in plasma-forming space 612. Further, a pre-coating material is supplied into plasma-forming space 612 via a pre-coating material source (not shown). The pressure within plasma-forming space 612 and the voltage differential, as created by upper RF driver 608, are set such that the pre-coating material supplied into plasma-forming space 612 creates plasma 616. Plasma 616 deposits the pre-coating material onto the surfaces of confinement chamber portion 602 and electrode 604 that are exposed to plasma-forming space 612. Because ESC 606 is not connected to ground and is not connected to RF source 610, ESC 606 is RF-floating. Because confinement chamber portion 602 is grounded via ground connection 618, confinement chamber portion 602 forms a closed current loop with upper electrode 604.

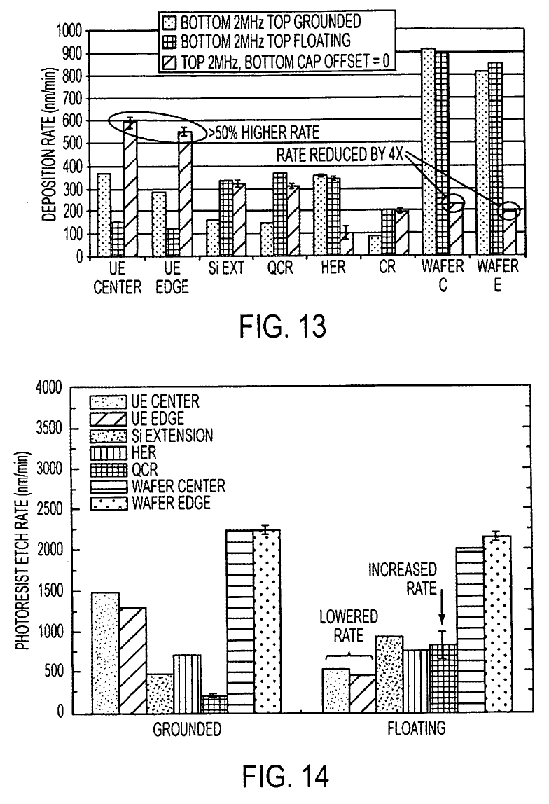

Consequently, an RF current 622 is forced into plasma 616 from upper electrode 604 toward confinement chamber portion 602, which is grounded. RF current 622 cannot enter the ESC 606, as it is excluded from the circuit. Plasma 616 is then pushed along with RF current 622. Therefore, the majority of plasma 616 has a toroidal shape having a majority remaining close to an inner surface 626 of confinement chamber portion 602 and a portion remaining close to a bottom surface 624 of electrode 604. As a result pre-coating rates at bottom surface 624 of electrode 604 may be increased by at least 50% over the conventional methods. Similarly, pre-coating rates at an upper surface 628 of ESC 606 may be decreased, by a factor of four as shown in FIG. 13, which will be discussed in more detail below.

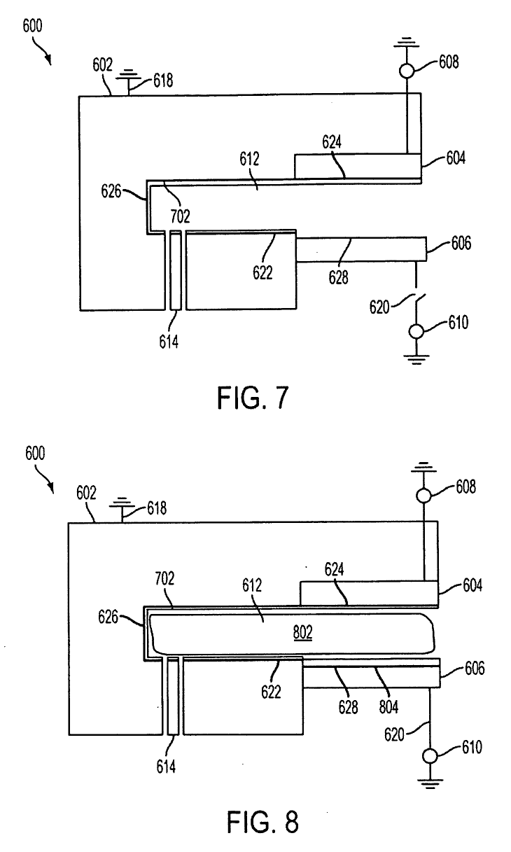

FIG. 7 illustrates the chamber system of FIG. 6, after an exemplary pre-coat process in accordance with the present invention. In FIG. 7, a layer 702 of pre-coating material covers bottom surface 624 of upper electrode 604 and inner surface 626 of confinement chamber portion 602. However, in contrast with the conventional system and method discussed above with respect to FIG. 2, in accordance with the present invention, no pre-coating material covers upper surface 628 of ESC 606. Therefore, less pre-coating material is required in accordance with the present invention. The required amount of pre-coating material is dictated by the required thickness at bottom surface 624 of upper electrode 604. Specifically, the amount of pre-coating material is tailored such that at the end of the etch process, the pre-coating material just starts to clear from bottom surface 624 of upper electrode 604. Advantages of not having a layer of pre-coating material on ESC 606 include: 1) less time being required to remove remaining pre-coating material during WAC as compared to conventional methods; 2) wafer clamping via ESC 606 becomes more reliable since no additional film is present between top surface 628 of ESC 606 and a wafer; and 3) the likelihood of generating small particles when the wafer is lifted from ESC 606, resulting from pulling up portions of pre-coating material from top surface 628 of the ESC 606, decreases.

FIG. 8 illustrates the chamber system of FIG. 6, during an exemplary wafer processing process in accordance with the present invention. In the figure, a wafer 804 is held on ESC 606 via an electrostatic force. A voltage differential is provided between electrode 604 and ESC 606, via upper RF driver 608 and lower RF driver 610, while the pressure is decreased in plasma-forming space 612. Further, an etching material is supplied into plasma-forming space 612 via an etching material source (not shown). The pressure within plasma-forming space 612 and the voltage differential, as created by at least one of upper RF driver 608 and lower RF driver 610, are set such that the etching material supplied into plasma-forming space 612 creates plasma 802. Plasma 802 etches material within plasma-forming space 612, which includes wafer 804 in addition to layer 702 of pre-coating material on bottom surface 624 of electrode 604 and inner surface 626 of confinement chamber portion 602. Layer 702 of precoating material on bottom surface 624 of electrode 604 and inner surface 626 of confinement chamber portion 602 protects the underlying surfaces from direct plasma attack and is consumed during wafer processing.

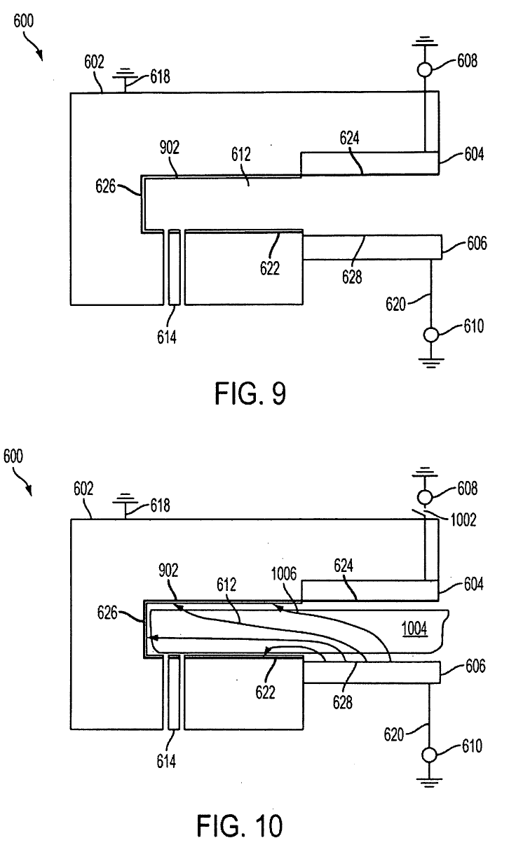

FIG. 9 illustrates the chamber system of FIG. 6, after an exemplary wafer processing process in accordance with the present invention. In the figure, wafer 804 has been removed from the top of ESC 606. The portion of layer 702 of pre-coating material on bottom surface 624 of electrode 604 has been removed because the amount of coating is typically pre-determined to last until in the end the wafer etching process to eliminate coating from electrode 604. However, a thinned layer 902 of pre-coating material remains on inner surface 626 of confinement chamber portion 602. More importantly, in contrast the conventional system and method discussed above with respect to FIG. 4, in accordance with the present invention, no pre-coating material remains on upper surface 628 of ESC 606. This is because no pre-coating material was deposited on upper surface 628 of ESC 606 in the pre-coating process discussed above with respect to FIG. 7.

In order to prepare for a new wafer processing session, in contrast with the conventional system and method discussed above with respect to FIG. 4, in accordance with the present invention, only thinned layer 902 of pre-coating material on inner surface 626 of confinement chamber portion 602 should be removed. This may be accomplished via a wafer-less auto-clean (WAC) process as discussed below. Since no pre-coating material needs to be removed from top surface 628 of ESC 606, and since layer 902 of pre-coating material is thinner than layer 626 of pre-coating material, as a result of the etch process, significantly less time is required in the WAC process. This represents a through-put advantage besides the advantage of saving cleaning material and RF power.

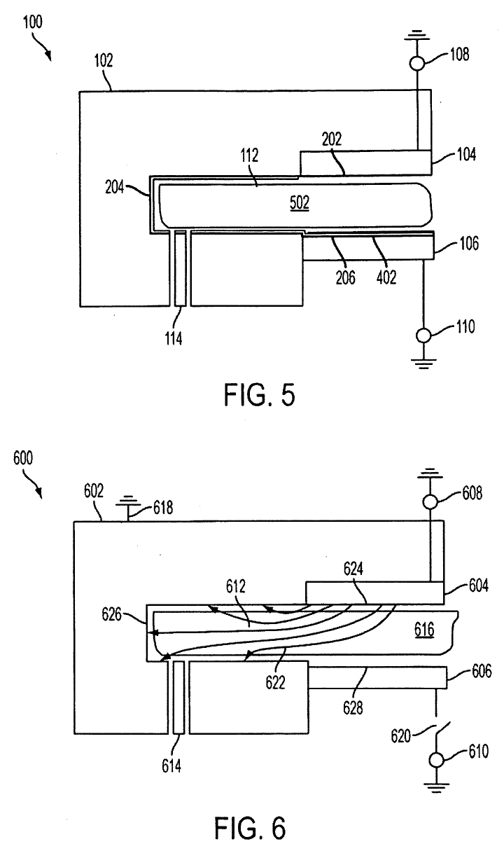

FIG. 10 illustrates the chamber system of FIG. 6, during an example WAC process in accordance with the present invention. Contrary to the conventional WAC process discussed above with respect to in FIG. 5, which continues until all the pre-coating material is removed from the ESC, in accordance with an aspect the present invention, die WAC process need only continue until layer 902 of pre-coating material is removed.

As illustrated in FIG. 10, system 600 further includes switch 1002 that is capable of disconnecting upper RF driver 608 from electrode 604. At the same time, opening switch 1002 will also electrically float the upper electrode as no connection to ground is provided. In order to remove layer 902 of pre-coating material from inner surface 626 of confinement chamber portion 602, cleaning plasma is exposed to inner surface 626 of confinement chamber portion 602. This is accomplished by providing a voltage differential between ESC 606 and confinement chamber portion 602, via lower RF driver 610, while the pressure is decreased in plasma-forming space 612. Further, a cleaning material is supplied into plasma-forming space 612 via a cleaning material source (not shown). The pressure within plasma-forming space 612 and the voltage differential, as created by lower RF driver 610, are set such that the cleaning material supplied into plasma-forming space 612 creates plasma 1004. Plasma 1004 etches layer 902 of pre-coating material from inner surface 626 of confinement chamber portion 602. Because electrode 604 is not connected to ground and is not connected to RF source 608, electrode 604 is RF-floating. Because confinement chamber portion 602 is grounded via ground connection 618, confinement chamber portion 602 forms a closed current loop with ESC 606.

Consequently, an RF current 1006 is forced into plasma 1004 from ESC 606 toward confinement chamber portion 602, which is grounded. RF current 1006 cannot enter the electrode 604, as it is excluded from the circuit. Plasma 1004 is then pushed along with RF current 1006. Therefore, the majority of plasma 1004 has a toroidal shape having a majority remaining close to an inner surface 626 of confinement chamber portion 602 and a portion remaining close to top surface 628 of ESC 606. Layer 902 of pre-coating material from inner surface 626 of confinement chamber portion 602 is then removed by plasma 1004.

In accordance with this aspect of the present invention, wear rates at the upper electrode 604 are decreased by a factor of three over that of conventional WAC processes in conventional systems. Further, in accordance with this aspect of the present invention, removal rates are also increased at grounded surfaces in the plasma periphery, which are difficult to clean with conventional WAC processes in conventional systems.

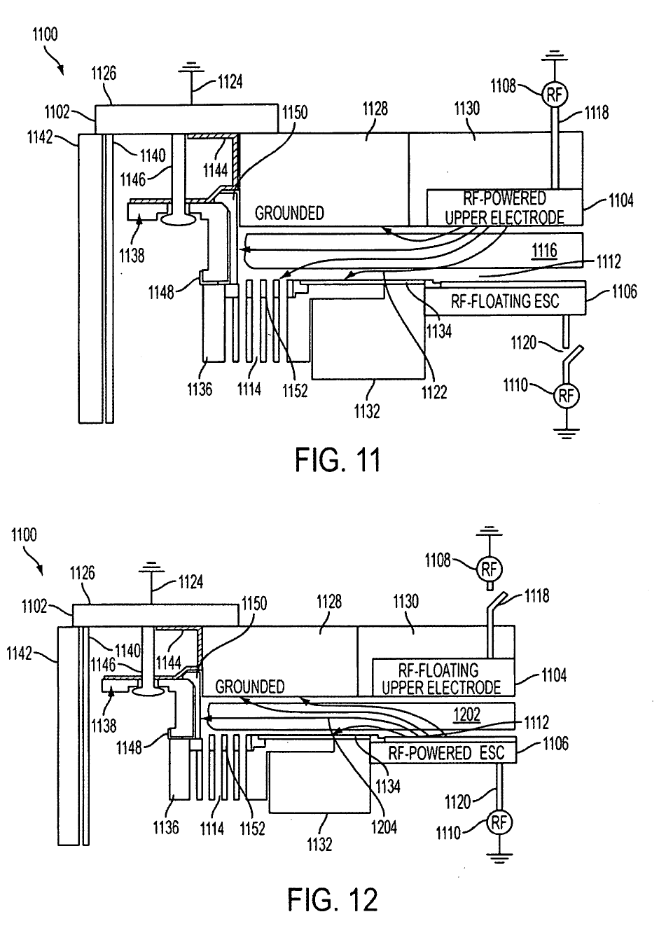

FIG. 11 illustrates another exemplary wafer processing system during an exemplary pre-coating process in accordance with the present invention. In the figure, system 1100 includes a confinement chamber portion 1102, an electrode 1104, an ESC 1106, an upper RF driver 1108 connectable to electrode 1104 via a switch 1118, a lower RF driver 1110 connectable to ESC 1106 via a switch 1120, and an exhaust portion 1114. A plasma-forming space 1112 is bounded by electrode 1104, ESC 1106, and confinement chamber portion 1102. Further, confinement chamber portion 1102 is grounded with ground connection 1124.

In this example, confinement chamber portion 1102 is illustrated in more detail. Specifically, confinement chamber portion 1102 includes a top plate 1126, an upper electrode outer extension 1128, a heater I 130, a lower ground portion 1132, a dielectric cover 1134, an lower ground portion outer wall 1136, an RF shield 1138, a chamber liner 1140, a chamber wall 1142, a flexible RF strap 1144, a confinement ring hanger 1146, a gasket 1148, a confinement ring 1150 and an exhaust cover 1152.

Top plate 1126, upper electrode outer extension 1128, heater 1130, lower ground portion 1132 and chamber wall 1142 comprise a housing of system 1100. Heater 1130 is operable to heat system 1100 if required. Dielectric cover 1134 protects lower ground portion 1132 from plasma wear, whereas exhaust cover 1152 protects exhaust portion 1114 from plasma wear. Each of dielectric cover 1134 and exhaust cover 1152 may comprise known plasma resistive materials, a non-limiting example of which includes quartz. Inner chamber outer wall 1136 provides an outer housing for plasma forming space 1112 and a lower support for RF shield 1138. RF shield 1138 rests on lower ground portion outer wall 1136 and prevents RF current from escaping plasma forming space 1112. Chamber liner 1140 is a removable insert that enables easy cleaning outside the chamber. Flexible RF strap 1144 provides ground connection to RF shield 1138 and confinement ring 1150. Confinement ring hanger 1146 provides support for confinement ring 1150 via top plate 1126. Gasket 1148 ensures ground connection between RF shield 1138 and lower ground portion outer wall 1136. Confinement ring 1150 confines plasma 1116 within plasma forming space 1112.

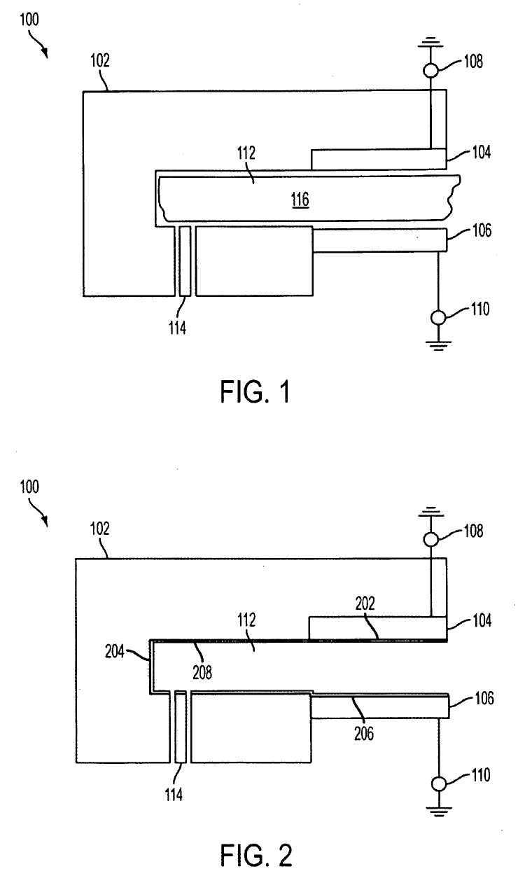

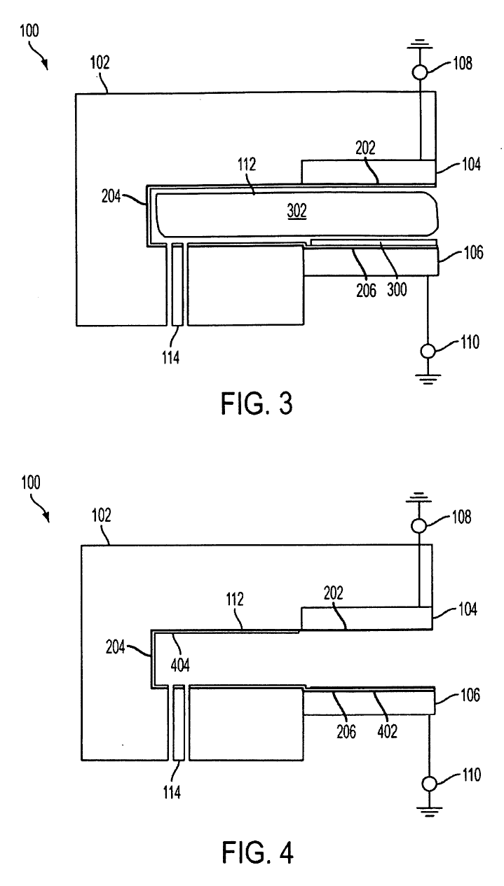

In accordance with an aspect of this embodiment, the top portion of system 1100 may be removed from a bottom portion. In particular, top plate 1126, upper electrode outer extension 1128, heater 1130, RF shield 1138, flexible RF strap 1144, confinement ring hanger 1146, gasket 1148, confinement ring 1150 and exhaust cover 1152 may be removed for servicing. Further, confinement ring 1150 is replaceable. As such, in contrast to a conventional system for example as discussed above with respect to FIG. 1, in the present example, the entire confinement chamber portion need not be replaced as a result of service wear. The replacement cost of confinement ring 1150 is much lower than the replacement cost of an entire confinement chamber portion of a conventional system. As such, the operational cost of system 1100 is much lower than that of the convention system.

During an exemplary pre-coating process, upper electrode 1104 is powered by upper RF driver 1108 via switch 1118. Further, during the pre-coating process, ESC 1106 is disconnected from lower RF driver 1110 and from ground, and is therefore RF-floating. Similar to system 600 discussed above with respect to FIG. 6, during a pre-coating process in system 1100, an RF current 1122 is transmitted through plasma 1116 from upper electrode 1104 toward the grounded periphery, which includes upper electrode outer extension 1128, dielectric cover 1134 on lower ground portion 1132, exhaust cover 1152 and confinement ring 1150.

FIG. 12 illustrates the system of FIG. 11, during an exemplary WAC process in accordance with the present invention. Similar to system 600 discussed above with respect to FIG. 10, during a WAC process in system 1100, an RF current 1204 is transmitted through plasma 1202 from ESC 1106 toward the grounded periphery, which includes upper electrode outer extension 1128, dielectric cover 1134 on lower ground portion 1132, exhaust cover 1152 and confinement ring 1150. Upper electrode 1104 is disconnected from RF source 1108 and from ground due to switch 1118 being open. Upper electrode 1104 is therefore electrically floating.

FIG. 13 is a chart comparing three separate deposition scenarios of system 1100. In a first deposition scenario, electrode 1104 is connected to ground and ESC 1106 is driven by lower RF driver at 2 MHz. In a second deposition scenario, electrode 1104 is floating and ESC 1106 is driven by lower RF driver at 2 MHz. In a third deposition scenario, electrode 1104 is driven by upper RF driver at 2 MHz and ESC 1106 is floating.

In the figure, deposition rates (nm/min) are measured at the center of electrode 1104 (UE center), die edge of electrode 1104 (UE edge), upper electrode outer extension 1128 (Si ext), exhaust cover 1152 (QCR), the hot edge ring (HER), confinement ring 1150 (CR), the wafer center (Wafer C) and the wafer edge (Wafer E). In each group of bars in the chart, the left bar represents the first deposition scheme, the middle bar represents the second deposition scheme and the right bar represents the third deposition scheme.

FIG. 13 shows that the third deposition scheme, e.g., a deposition scheme in accordance with an aspect of the present invention, increases the deposition rate on upper electrode to more than 50% over that of conventional scheme, i.e., the first deposition scheme. Further, the deposition rate on the ESC (Wafer C and Wafer E when no wafer is present) in accordance with the present invention is reduced by a factor of four over that of the conventional scheme.

FIG. 14 is a chart comparing two separate WAC scenarios of system 1100. In a first WAC scenario, electrode 1104 is connected to ground and ESC 1106 is driven by lower RF driver at 2 MHz. In a second WAC scenario, electrode 1104 is floating and ESC 1106 is driven by lower RF driver at 2 MHz.

In the figure, etch rates (nm/min) are measured at the center of electrode 1104 (UE center), the edge of electrode 1104 (UE edge), upper electrode outer extension 1128 (Si ext), exhaust cover 1152 (QCR), the hot edge ring (HER), confinement ring 1150 (here represented by QCR due to the proximity of both parts), the wafer center (Wafer C) and the wafer edge (Wafer E). The left group of bars in the chart represents the first WAC scheme, whereas the right group of bars represents the second WAC scheme.

It is clear from the figure, that the photo resist etch rate (wear rate) on upper electrode in the second WAC scheme, i.e., the WAC process in accordance with an aspect of the present invention, is about a factor of three times lower than the first WAC scheme, i.e., the conventional WAC process. Further, the wear rate on the periphery (QCR, Si extension) in the second WAC scheme, i.e., the WAC process in accordance with an aspect of the present invention, is about a factor of three times higher than the first WAC scheme, i.e., the conventional WAC process. Both outcomes represent a benefit as they allow for a reduction of the total WAC time to clean all hardware thereby increasing throughput.

In the example embodiments discussed above, with respect to FIGS. 6-12, the wafer processing system has a switch system that includes a first switch that is operable to connect/disconnect the electrode to/from an RF driver and a second switch that is operable to disconnect/connect the ESC from/to another RF driver. In other embodiments, a switch system includes a single switch having a first state, wherein the electrode is connected to an RF driver and the ESC is disconnected from the same RF driver, and having a second state, wherein the electrode is disconnected from the RF driver and the ESC is connected to the same RF driver. In still other embodiments, a switch system includes a single switch having a first state, wherein the electrode is connected to a first RF driver and the ESC is disconnected from a second RF driver, and having a second state, wherein the electrode is disconnected from the first RF driver and the ESC is connected to the second RF driver.

In accordance with an aspect of the present invention, an ESC is established to be RF-floating, whereas a confinement chamber portion is grounded during a pre-coating process. Accordingly, the confinement chamber portion and the upper electrode are selectively targeted for pre-coating material deposition. As such, the amount of pre-coating material that is deposited onto the ESC is greatly reduced over that of conventional systems. Therefore, less time, energy and material are needed to remove pre-coating material from the ESC during a WAC process.

In accordance with another aspect of the present invention, an upper electrode is established to be RF-floating, whereas the confinement chamber portion is grounded during a WAC process. As such, the cleaning material is selectively targeted toward the confinement hardware portion of the chamber and toward the ESC where it is needed. Therefore, the upper electrode is subjected to less wear during a WAC process.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The exemplary embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to be protected by Letters Patent of the United States is:

1. A method of operating a wafer processing system having an electrode, an electrostatic chuck, a confinement chamber portion, a first radio frequency driving source, a second radio frequency driving source, a pre-coating material source, a cleaning material source, an exhaust portion and a switch system, the electrode being spaced from and opposing the electrostatic chuck, a plasma-forming space being bounded by the electrode, the electrostatic chuck and the confinement chamber portion, the first radio frequency driving source being arranged to be in electrical connection with the electrode via the switch system, the second radio frequency driving source being arranged to be in electrical connection with the electrostatic chuck via the switch system, the pre-coating material source being operable to provide a pre-coating material into the plasma-forming space, the cleaning material source being operable to provide a cleaning material into the plasma-forming space, the exhaust portion being operable to remove pre-coating material and cleaning material from the. plasma-forming space, said method comprising:
performing at least one of a pre-coating process and a cleaning process,
wherein the pre-coating process comprises
connecting the first radio frequency driving source to the electrode via the switch system,
connecting the confinement chamber portion to ground,
disconnecting the second radio frequency driving source from the electrostatic chuck via the switch system,
disconnecting the electrostatic chuck from ground,
supplying the pre-coating material into the plasma-forming space via the pre-coating material source,
generating a plasma within the plasma-forming space, and
coating the pre-coating material onto the confinement chamber portion, and
wherein the cleaning process comprises
disconnecting the first radio frequency driving source from the electrode via the switch system,
disconnecting the electrode from ground,
connecting the confinement chamber portion to ground,
connecting the second radio frequency driving source to the electrostatic chuck via the switch system,
supplying the cleaning material into the plasma-forming space via the cleaning material source,
generating a plasma within the plasma-forming space, and cleaning the pre-coating material from the confinement chamber portion.

2. The method of claim 1, wherein said performing at least one of a precoating process and a cleaning process comprises performing the pre-coating process.

3. The method of claim 1, wherein said performing at least one of a pre-coating process and a cleaning process comprises performing the cleaning process.

4. The method of claim 1, wherein said performing at least one of a pre-coating process and a cleaning process comprises performing the pre-coating process and performing the cleaning process.
